(19) United States
(12) Patent Application Publication
(10) Pub. No.: US 2020/0052196 A1
(43) Pub. Date: Feb. 13, 2020

(54) Avoiding Oxygen Plasma Damage During Hard Mask Etching in Magnetic Tunnel Junction (MTJ) Fabrication Process

(71) Applicant: Taiwan Semiconductor Manufacturing Company, Ltd., Hsinchu (TW)

(72) Inventors: Dongna Shen, San Jose, CA (US); Yi Yang, Fremont, CA (US); Yu-Jen Wang, San Jose, CA (US)

(21) Appl. No.: 16/056,770

(22) Filed: Aug. 7, 2018

(51) Int. Cl. H01L 43/12; H01F 41/34; H01L 43/02; H01F 10/32

(52) U.S. Cl. CPC H01L 43/12; H01F 41/34; H01L 43/02; H01L 43/10; H01F 10/3272; H01F 10/3286; H01F 10/3259

(57) ABSTRACT

An etch process flow for forming magnetic tunnel junction (MTJ) cells with enhanced throughput that also increases the magnetoresistive ratio and decreases critical dimension (CD) variation is disclosed. A photoresist pattern is formed on a dielectric antireflective coating (DARC), which contacts a top surface of a hard mask (HM) that is an uppermost MTJ layer. After a first ion beam etch (IBE) or reactive ion etch (RIE) transfers the pattern through the DARC, a second etch is used to transfer the pattern through the HM. The second etch includes an oxidant to passivate the pattern sidewalls and completely removes the photoresist layer because of one or both of a thicker DARC and thicker HM than in conventional processing. Accordingly, an oxygen etch typically used to remove the photoresist after the HM etch is avoided and thereby provides improved MTJ performance, especially for CDs<60 nm.

### RELATED PATENT APPLICATIONS

This application is related to U.S. Pat. No. 9,887,350; Docket #HT17-011, Ser. No. 15/668,113, filing date Aug. 3, 2017; and Docket #HT17-051, Ser. No. 15/856,129, filing date Dec. 28, 2017; which are assigned to a common assignee and herein incorporated by reference in their entirety.

### TECHNICAL FIELD

The present disclosure relates to a pattern in a photoresist layer that is transferred through a dielectric antireflective coating (DARC), hard mask, and underlying stack of MTJ layers with an etch process including a plurality of ion beam etch (IBE) steps, a plurality of reactive ion etch (RIE) steps, or a combination of RIE and IBE steps, and in particular to providing one or both of a thicker DARC and thicker hard mask to ensure the photoresist is removed during the hard mask etch and to avoid stripping the photoresist with an oxygen ashing step thereby improving the magnetoresistive (MR) ratio and minimizing CD variation in the final device.

### BACKGROUND

A MTJ memory element is also known as a MTJ cell and is a key component in memory devices such as magnetoresistive random access memory (MRAM) and spin torque transfer (STT)-MRAM. An important process in fabricating an array of MTJ cells is the etch transfer of a photoresist pattern through a hard mask, which serves as an etch mask for subsequent etching through an underlying MTJ stack of layers. Each MTJ cell has a critical dimension (CD) that in state of the art devices is substantially less than 100 nm from a top-down view. The etch transfer steps comprise one or both of RIE and IBE. Typically, there is a DARC between the photoresist layer and hard mask to improve CD uniformity in the photoresist pattern that comprises island shapes arrayed in rows and columns.

A MTJ stack of layers includes two ferromagnetic layers called the free layer (FL) and reference layer (RL), and a dielectric layer (tunnel barrier) between the FL and RL. The RL has a fixed magnetization preferably in a perpendicular-to-plane direction (perpendicular magnetic anisotropy or PMA) while the FL is free to rotate to a direction that is parallel or anti-parallel to the RL magnetization direction thereby establishing a “0” or “1” memory state for the MTJ. The MR ratio is expressed by dR/R where dR is the difference in resistance between the parallel state resistance (Rp) and the anti-parallel state resistance (Rap), and R is the minimum resistance value (Rp). Forming a MTJ with a higher MR ratio means the Rp and Rap states are more easily determined during a read process.

The hard mask is typically a metal or metal nitride that has sufficient resistance to RIE and IBE in order to remain substantially intact and maintain the desired CD during the etch process through the underlying MTJ stack of layers. The etch process is challenging since there are a variety of materials (magnetic alloys, non-magnetic metals, and dielectric films) in the MTJ stack that each have a different etch rate, and the hard mask should have high etch selectivity with respect to each layer. The etch process requires a delicate balance between physical and chemical etch components. For example, RIE with pure Ar plasma, and IBE cause no chemical damage along MTJ sidewalls, but IBE or RIE based only on noble gas has poor etch selectivity between hard mask and MTJ layers such that a hard mask of up to 50% thicker is required than for RIE processes comprising a chemical reactant. Accordingly, formation of high density MTJ arrays with a CD substantially less than 100 nm is difficult because of a high aspect ratio in the photoresist pattern due to the added hard mask thickness. Moreover, pure Ar RIE and IBE are associated with substantial redeposition of hard mask and bottom electrode metals on MTJ sidewalls. As a result, a shunting path is easily formed on the MTJ sidewalls and leads to shorts and low yields of the memory device.

RIE plasma that is generated from oxidants such as methanol is known to provide MTJ sidewalls substantially free of residue. However, RIE with chemical etchants does cause chemical and plasma damage on MTJ sidewalls. Therefore, a combination of physical and chemical etchants has been used to minimize redeposition of hard mask and bottom electrode material on MTJ sidewalls while also minimizing chemical damage to the sidewalls.

Another concern is the removal of the photoresist layer once the pattern has been transferred through the hard mask. Generally, an oxygen etch is employed to remove the photoresist before the MTJ etch but this step has a tendency to damage sidewalls of the free layer, and redeposit material to form rough HM sidewalls, especially when using Ru as the MTJ capping layer, and the stopping layer for HM-etching because of a high Ru etching rate under O₂ plasma. Subsequent treatments to repair the damaged MTJ sidewalls are unsuccessful, and low product yields and considerable CD variation (high Rp covariance or Rp_cov) are observed. Therefore, a new process flow is needed for transferring a photoresist pattern through a hard mask and an underlying MTJ stack without causing permanent damage to free layer integrity. An improved process is especially important for fabricating MTJ cells with a CD that is 60 nm or less.

### SUMMARY

One objective of the present disclosure is to provide an etch process for transferring a photoresist pattern through a hard mask and underlying MTJ stack of layers so that CD variation is minimized, and the resulting MTJ cell including free layer sidewalls is not damaged.

A second objective of the present disclosure is to provide the etch process according to the first objective that provides enhanced throughput compared with a process of record (POR), and is especially effective for MTJ cells having a critical dimension (CD)<60 nm.

According to a preferred embodiment, these objectives are achieved by providing a MTJ stack of layers having at least a reference layer, free layer, a tunnel barrier between the free layer and reference layer, and an uppermost hard mask. In some embodiments, a seed layer is employed as the bottommost MTJ layer on a substrate that is a bottom electrode in a memory device. A pattern comprising a plurality of island features with the desired CD for the eventual MTJ cells is first defined in a photoresist mask layer above the hard mask layer. In preferred embodiments, there is a dielectric anti-reflective coating (DARC) such as SiO₂, Si₃N₄, SiCOH, or SiON between the hard mask (HM) and photoresist mask layer to improve CD uniformity in the photoresist pattern. The photoresist pattern is transferred through the DARC by a first RIE or IBE step, and is then transferred through the hard mask by continuing the first etch step, or by performing a second RIE step comprised of a fluorocarbon or chlorocarbon gas, or with a second IBE step. Preferably, the HM etch also comprises an oxidant such as air, O₂, methanol, ethanol, H₂O₂, H₂O, N₂O, NH₃, or CO to serve as a passivation step which forms smoother HM sidewalls and reduces CD variation in the final device.

A key feature is that the HM etch consumes the photoresist layer remaining after the etch transfer through the DARC thereby avoiding the need for a subsequent O₂ etch (between the HM etch and MTJ etch) that is known to damage the MTJ including free layer sidewalls. According to one embodiment, the DARC thickness is substantially increased compared with a conventional scheme while maintaining HM thickness to ensure the photoresist is entirely consumed during the HM etch. In an alternative embodiment, DARC thickness is maintained while HM thickness is substantially increased. Moreover, both DARC thickness and HM thickness may be increased at the same time.

The pattern of island features is then transferred through the remaining MTJ layers by a RIE or IBE process comprising a main etch step during a first period of time (t1) wherein plasma or ions that are generated from a noble gas, and one or more oxidants including but not limited to CH₃OH, C₂H₅OH, NH₃, O₂, H₂O₂, N₂O, H₂O, CO, and NH₃ are directed essentially orthogonal to the substrate in RIE, or at an angle from 0° to about 90° to the substrate for IBE. In particular, the noble gas ions and plasma provide a physical component while ions and plasma from the one or more oxidants provide a chemical etching component. As a result, the noble gas component minimizes chemical damage to the MTJ sidewalls, and redeposition of etched residue on the MTJ sidewalls is significantly reduced by the chemical component. Moreover, the oxidant enables non-volatile metal residues formed on MTJ sidewalls to be converted to metal oxide that are volatile under certain conditions.

A MTJ etch based on a RIE process may also comprise an over etch step immediately after the main etch step wherein the plasma based on the noble gas and oxidant is continued for a second period of time (t2) where t2 is typically less than or equal to t1. Although MTJ sidewalls are substantially formed during the main etch, the over etch step is advantageously employed to ensure a more complete removal of MTJ materials between adjacent sidewalls, and of redeposited material on MTJ sidewalls. Furthermore, the noble gas/oxidant flow rate ratio is increased during the over etch step in some embodiments in order to minimize chemical damage to the MTJ sidewalls.

According to another embodiment of the present disclosure, the MTJ etch process further comprises an IBE or plasma cleaning step after the main etch and over etch steps. When IBE is selected for the cleaning step, the incident angle of the ions may be between 0° to 90° with respect to the substrate thereby including a horizontal component that is beneficial in removing any remaining sidewall residue. Furthermore, one or more oxidants may be added to the noble gas in the IBE chamber to oxidize any metal residue that remains on MTJ sidewalls. With a plasma etch for the cleaning step, a RF power preferably ≤100 Watts is used to generate a plasma from a noble gas or a combination of noble gas and oxidant. In this case, the plasma is directed essentially orthogonal to the substrate. Moreover, the plasma etch may be performed in the same mainframe as a subsequent encapsulation process to avoid exposing clean MTJ sidewalls to air, O₂, or H₂O. A first step in the encapsulation process is to deposit a first sub-layer on the MTJ sidewalls and on exposed portions of substrate.

Thereafter, a second encapsulation sub-layer is deposited on MTJ cells to fill gaps between adjacent MTJ sidewalls, and then a chemical mechanical polish (CMP) process is performed to remove all layers above the hard mask. The CMP process forms a HM top surface that is coplanar with the surrounding encapsulation layer top surface. A top electrode layer is then formed on the encapsulation layer (comprised of first and second sub-layers) and on the plurality of MTJ cells such that each MTJ cell is between a bottom electrode and a top electrode to yield a plurality of memory devices.

### BRIEF DESCRIPTION OF THE DRAWINGS

FIG. 1 is a cross-sectional view of a MTJ stack of layers on which a photoresist pattern has been formed, and shows ions used to transfer the pattern through an underlying DARC during an etch process.

FIG. 2 is a cross-sectional view of a MTJ stack in FIG. 1 after an etch step transfers the pattern through the uppermost hard mask MTJ layer that is thin enough such that a portion of the photoresist layer remains on the DARC.

FIG. 3 shows a prior art oxygen etch process that is used to remove the photoresist layer in FIG. 2 but has a tendency to damage the MTJ free layer.

FIG. 4 shows a photoresist layer that has been patternwise exposed and developed on a top surface of a DARC that is formed on a MTJ stack of layers according to an embodiment of the present disclosure.

FIG. 5 and FIG. 6 are cross-sectional views depicting an etch process through a thick DARC and through a hard mask (HM), respectively, such that the photoresist layer in FIG. 4 is entirely removed before the end of the HM etch according to an embodiment of the present disclosure.

FIG. 7 is a cross-sectional view showing a MTJ cell that is formed by a MTJ etch process where the DARC and HM in FIG. 6 serve as etch masks according to an embodiment of the present disclosure.

FIG. 8 is a cross-sectional view of the MTJ cell in FIG. 7 showing ions directed at a non-vertical angle during an optional IBE cleaning step to remove residue on MTJ sidewalls after the MTJ etch process.

FIG. 9 is a cross-sectional view of the MTJ cell in FIG. 8 following deposition of an encapsulation layer and planarization to electrically isolate the MTJ cell.

FIG. 10 is a top-down view of a plurality of MTJ cells having a circular shape in an array of rows and columns according to an embodiment of the present disclosure.

FIG. 11 and FIG. 12 are cross-sectional views depicting an etch process through a DARC and through a thick hard mask (HM), respectively, such that the photoresist is entirely removed during the HM etch according to another embodiment of the present disclosure.

FIG. 13 shows a plot of MR ratio (DRR) vs. MTJ cell CD for a process of record (POR) MTJ etch sequence, and for a process flow according to an embodiment of the present disclosure.

FIG. 14 is a plot of Rp_cov % vs. MTJ cell CD for a POR MTJ etch sequence, and for a process flow according to an embodiment of the present disclosure.

### DETAILED DESCRIPTION

The present disclosure is an etch process that transfers a pattern in a photoresist layer sequentially through a DARC, hard mask, and underlying MTJ stack of layers to form a plurality of MTJ cells, and where the photoresist is completely removed before the end of the hard mask etch step. Only one MTJ cell is depicted in the drawings with cross-sectional views in order to simplify the drawings. A process is defined as a method that includes a plurality of steps. The resulting MTJ cells may be used in MRAM, STT-MRAM, spin torque oscillators (STO), sensors, and biosensors. In the drawings, a thickness of a layer is shown in the z-axis direction while a top surface of each layer is formed in a plane along the x-axis and y-axis directions.

In related patent application US 2016/0351798, we disclosed a process flow where a photoresist mask layer is formed directly on a hard mask, and the HM etch is then performed with conditions comprising air, oxygen, or water to generate smoother MTJ sidewalls and more uniform MTJ shapes from a top-down view. Furthermore, HM passivation with oxygen, for example, is necessary before the photoresist mask is stripped.

In related patent application Ser. No. 15/668,113, the photoresist pattern is formed on a DARC layer, and is transferred through the DARC before the HM etch. The HM etch may remove the photoresist mask layer in some embodiments, but in other embodiments, the photoresist layer is not stripped until after HM sidewall passivation.

Now we have discovered an improved process flow for the HM etch and subsequent MTJ etch that combines the HM passivation, HM etch, and photoresist removal into one step for faster throughput, and better MTJ performance in terms of less CD variation (smaller Rp_cov %), and enhanced MR ratio compared with a process of record (POR) employed by the inventors.

In FIG. 1, MTJ layers 11-15 are sequentially formed on a substrate 10 that in one embodiment is a bottom electrode in a memory device. The substrate is formed on a sub-structure (not shown) that is fabricated on a wafer as appreciated by those skilled in the art. The bottom electrode may be a multilayer structure comprising conductive metals and alloys such as Ta, TiN, and TaN, and is typically embedded in a dielectric layer (not shown). In the exemplary embodiment, the MTJ stack has a bottom spin valve configuration wherein a seed layer 11, pinned or reference layer 12, tunnel barrier 13, free layer 14, and hard mask 15 are sequentially formed on the substrate. However, the present disclosure also anticipates the MTJ stack may have a top spin valve configuration where the positions of the free layer and reference layer in FIG. 1 are reversed, or a dual spin valve configuration that is well known in the art. Each of the reference layer and free layer preferably have perpendicular magnetic anisotropy (PMA) with a magnetization aligned in a positive or negative z-axis direction.

In other embodiments (not shown), at least one additional layer may be included in the aforementioned MTJ stack such as a Hk enhancing layer (i.e. MgO) between the free layer and hard mask that enhances PMA in the free layer. The Hk enhancing layer may also be W, Mo, or an alloy thereof rather than a metal oxide.

The seed layer 11 is a single layer or a multilayer, and may be comprised of one or more of NiCr, Ta, Ru, Ti, TaN, Cu, Mg, or other materials typically employed to promote a smooth and uniform grain structure in overlying layers.

Reference layer 12 preferably has a synthetic anti-parallel (SyAP) configuration represented by AP2/Ru/AP1 where an anti-ferromagnetic coupling layer made of Ru, Rh, or Ir, for example, is sandwiched between an AP2 magnetic layer and an AP1 magnetic layer (not shown). The AP2 layer, which is also referred to as the outer pinned layer is formed on seed layer 11 while AP1 is the inner pinned layer and typically contacts the tunnel barrier 13. AP1 and AP2 layers may be comprised of CoFe, CoFeB, Co, or a combination thereof. In other embodiments, one or both of the AP1 and AP2 layers may be a laminated stack with inherent PMA such as (Co/Ni)ₙ, (CoFe/Ni)ₙ, (Co/NiFe)ₙ, (Co/Pt)ₙ, (Co/Pd)ₙ, or the like where n is the lamination number. Furthermore, a transitional layer such as CoFeB, Co, or CoFeB/Co may be inserted between the laminated stack in the AP1 layer and the tunnel barrier layer.

The tunnel barrier layer 13 is preferably a metal oxide that is one or more of MgO, TiOx, AlTiO, MgZnO, Al₂O₃, ZnO, ZrOx, HfOx, or MgTaO. More preferably, MgO is selected as the tunnel barrier layer because it provides the highest MR ratio, especially when sandwiched between two CoFeB layers, for example.

The free layer 14 may be Co, Fe, CoFe, or an alloy thereof with one or both of B and Ni, or a multilayer stack comprising a combination of the aforementioned compositions. In another embodiment, the free layer may have a non-magnetic moment diluting layer such as Ta or Mg inserted between two CoFe or CoFeB layers that are ferromagnetically coupled. In an alternative embodiment, the free layer has a SyAP configuration such as FL1/Ru/FL2 where FL1 and FL2 are two magnetic layers that are antiferromagnetically coupled, or is a laminated stack with inherent PMA described previously with respect to the reference layer composition.

Hard mask (HM) 15 is also referred to as a capping layer and is typically comprised of one or more of Ta, Ru, TaN, Ti, TiN, and W. In other embodiments, the HM may comprise a metal, or an alloy such as MnPt that provides substantial resistance to subsequent etching and chemical mechanical polish (CMP) processes employed during MTJ fabrication and thereby preserves CD integrity. In our POR scheme, the HM has a thickness t1 of about 480 Angstroms. In general, the hard mask is an electrical conductor, and provides high etch selectivity relative to underlying MTJ layers during an etch process that forms MTJ cells with sidewalls that stop on the bottom electrode. All layers in the MTJ stack may be deposited in a DC sputtering chamber of a sputtering system such as an Anelva C-7100 sputter deposition system that includes ultra high vacuum DC magnetron sputter chambers with multiple targets and at least one oxidation chamber. Usually, the sputter deposition process involves Ar and a base pressure between 5×10⁻⁸ and 5×10⁻⁹ torr.

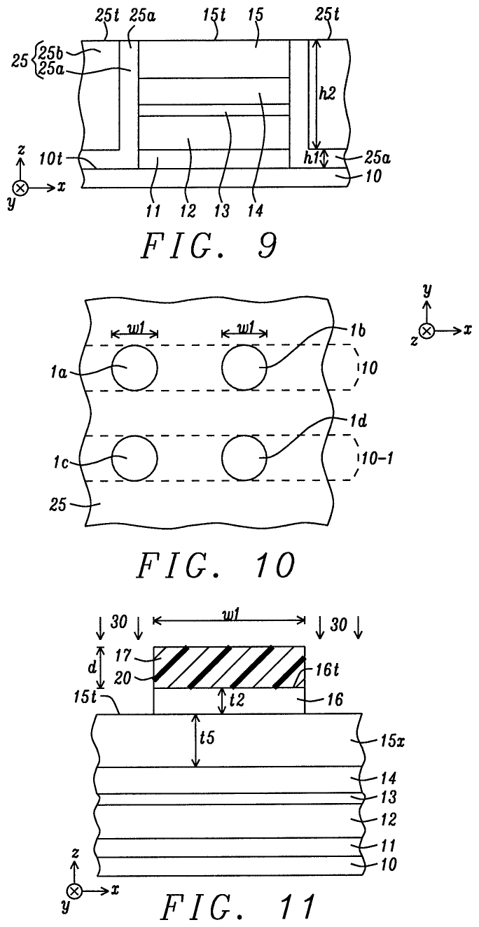

As a first step in the process flow of our POR scheme, a DARC 16, and a photoresist layer 17 are sequentially formed on the top surface 15t of the hard mask by well known methods. DARC is one or more of SiO₂, Si₃N₄, SiCOH, SiON, amorphous carbon, or black diamond with top surface 16t and thickness t2 of about 300 Angstroms, and has a refractive index that minimizes reflection of light during patternwise exposure of the photoresist layer thereby enabling more uniform island shapes with sidewalls 20 having less CD variation (more uniform w1) to be formed in the photoresist layer. A conventional patternwise exposure and developer sequence is employed to form a pattern in the photoresist layer that comprises a plurality of islands each with sidewall 20. As indicated later by a top-down view in FIG. 9, the resulting MTJ cells are in an array having a plurality of rows and columns. Each MTJ cell has a critical dimension w1 that in some embodiments is less than 60 nm, which is required in more advanced memory devices. Note that the devices may be circular such that w1 is formed in both of the x-axis and y-axis directions. In other embodiments, the top-down shape of island 17 in FIG. 1 (and the eventual MTJ cells in FIGS. 9-10) may be an ellipse or a polygon such that the y-axis dimension is different from the x-axis dimension.

After patterning photoresist layer 17, the island shape with sidewall 20 is transferred through the DARC 16 and reduces the photoresist layer thickness to d Etch step 30 may be an IBE with one or more of Ar, Kr, Xe, or Ne, or may comprise RIE with a fluorocarbon or chlorocarbon gas wherein ions or plasma are directed substantially orthogonal to hard mask top surface 15t. Moreover, oxygen may be flowed into the etch chamber during the IBE or RIE, or afterward as a passivation measure to form a smoother sidewall. As a result, sidewall 20 is extended along the DARC to a top surface 15t of the hard mask 15, and CD w1 is duplicated in the DARC.

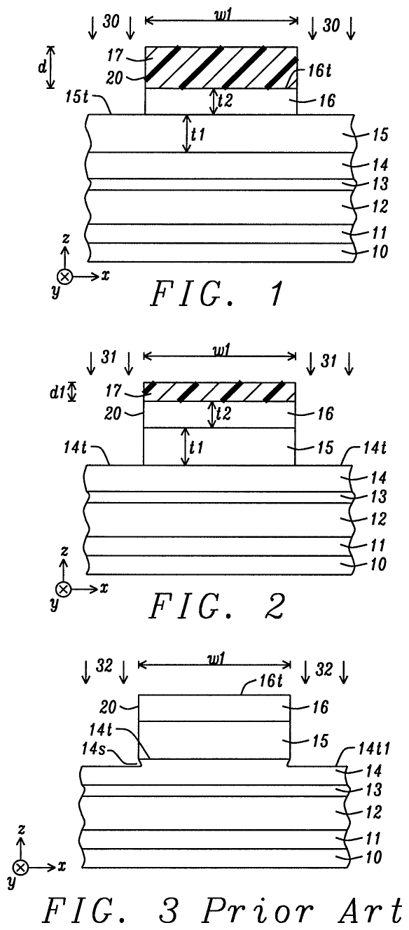

Referring to FIG. 2, a second etch step 31 is performed to transfer the island shape with sidewall 20 and CD w1 through the hard mask 15. In some embodiments, a second IBE with a noble gas, or a second fluorocarbon or chlorocarbon based RIE may be used wherein ions or plasma are directed substantially orthogonal to free layer top surface 14t. However, in other embodiments, the present disclosure anticipates that the conditions employed for etch step 31 are essentially the same as applied in etch step 30 such that the etch transfer through the hard mask may be a continuation of the etch transfer through DARC 16. Typically, the photoresist mask layer 17 has a thickness d1<d, but where d1>0 after the second etch or HM etch step.

Referring to FIG. 3, the POR scheme uses an oxygen etch 32 where ions or plasma strip the remaining photoresist mask layer 17 to expose top surface 16t of the DARC 16. Unfortunately, the oxygen etch is difficult to control, especially if the bottom portion of the HM 15 contacting the free layer 14 is a metal such as commonly used Ru that has a relatively high etch rate in oxygen. As a result, the oxygen etch may remove a portion of exposed free layer to form a FL top surface 14t1 outside sidewall 20 that is below the FL top surface 14t underneath the hard mask, and thereby exposes an upper portion of the FL sidewall 14s to oxygen damage. The oxygen etch may even continue into a portion of the free layer proximate to FL top surface 14t below the hard mask thereby significantly reducing PMA and thermal stability in the free layer. HM residue is also redeposited to generate a rough HM sidewall. The rough sidewall as well as FL oxidation at the FL top surface below the HM and at sidewall 20 cannot be reversed, and leads to a lower MR ratio and degrades performance in the final device.

Regarding FIGS. 4-8, an etch process is provided according to a first embodiment of the present disclosure wherein an oxygen etch of the photoresist mask layer is not included, and the HM etch step comprises passivation conditions to form smoother HM sidewalls. FIG. 4 shows photoresist layer 17 having a thickness d0 and an island pattern of width w1 on DARC top surface 16t after conventional patternwise exposure and development. DARC 16x has a thickness t3 where t3 is preferably at least two times greater than DARC thickness t2 in the POR scheme, and more preferably is proximate to 900 Angstroms while original photoresist thickness d0 of around 2600 Angstroms is maintained from the POR scheme to provide a key feature of entirely removing the photoresist layer 17 during the HM etch while simultaneously generating smooth HM sidewalls. The hard mask thickness t1 may be maintained proximate to 480 Angstroms from the POR scheme, or may be increased up to about 630 Angstroms in other embodiments.

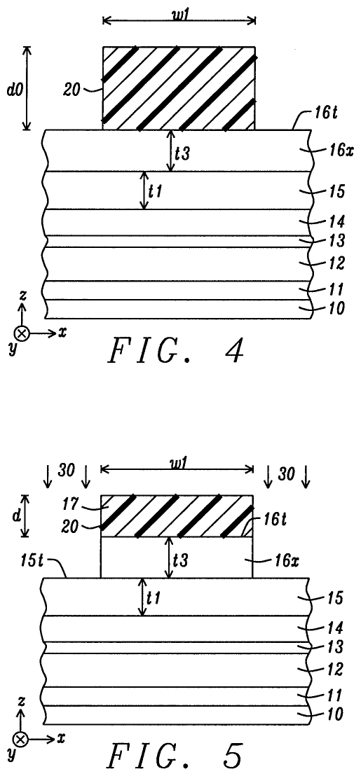

In FIG. 5, the first etch step 30 is retained from the POR scheme and is based on IBE with a noble gas or is a RIE comprised of a fluorocarbon or chlorocarbon. Furthermore, oxygen may be added as a passivation measure. However, the duration of the first etch is typically longer than in the POR scheme because of the additional DARC thickness in DARC 16x to be removed in regions not protected by photoresist layer 17. Since the relative etch rate is photoresist>DARC during the first etch step, typically a substantial portion of the photoresist layer is removed before the end of the first etch and original thickness d0 is reduced to d. Note that the etch rate (ER) ratio depends on the CD and the etch conditions where IBE has lower etch selectivity with a relative ER ratio closer to 1:1 than RIE meaning that during IBE, less photoresist will be removed during the first etch through the DARC compared with RIE. The first etch stops at HM top surface 15t.

The present disclosure anticipates that with a DARC thickness of >900 Angstroms, which is substantially larger than the HM thickness, and etch optimization such that the photoresist:DARC ER ratio is substantially greater than 1.25:1, then all of photoresist layer 17 may be removed during etch 30. In this case, the metal hard mask 15 will not be exposed to photoresist residue during subsequent etch 31p, which is expected to provide a smoother MTJ sidewall 20 after MTJ etch and lower CD variation.

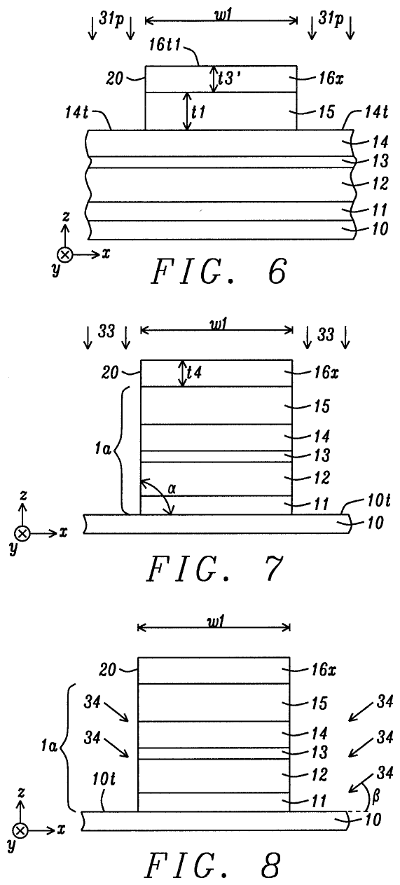

In FIG. 6, the second etch 31p according to the etch process flow of the present disclosure represents a modification of POR etch 31 because the second etch 31p comprises one or more oxidants including but not limited to air, O₂, methanol, ethanol, H₂O₂, H₂O, N₂O, NH₃, and CO that serve to passivate the HM sidewall that is part of sidewall 20. The second etch may be an IBE with noble gas or RIE comprised of a fluorocarbon or chlorocarbon. Accordingly, the second etch 31p removes any remaining photoresist layer and the thicker DARC 16x functions as the etch mask for removing unprotected regions of HM 15. Here, the relative ER is photoresist>DARC>HM. After the second etch is completed, DARC 16x has thickness t3′ that may be substantially less than t3 depending on the etch conditions that determine the photoresist/DARC etch rate ratio (generally between 1:1 and 1.25:1), and the DARC/HM etch rate ratio. More importantly, DARC top surface 16t1 is clear of photoresist and free layer top surface 14t is intact.

Referring to FIG. 7, the etch process flow according to a first embodiment of the present disclosure continues with a MTJ etch 33 that usually comprises a main etch step and an over etch step, and transfers the island shape in HM 15 through all of the underlying MTJ layers 11-14 thereby forming MTJ cell 1a. In a preferred embodiment, MTJ etch 33 comprises a physical component that is ions and plasma from a noble gas (Ar, Kr, Ne, or Xe), and a chemical component made of ions and plasma of a chemical (oxidant) species that are generated with RIE or IBE conditions. Thus, in a RIE embodiment, a noble gas and one or more oxidants including methanol, ethanol, NH₃, N₂O, H₂O₂, H₂O, O₂, air, and CO are fed into an etch chamber while a plasma is induced with a RF power at a temperature between room temperature and 80° C. The resulting ions and plasma are directed essentially orthogonal to the substrate top surface 10t. As a result, sidewall 20 is a continuous surface extending from HM top surface 15t to the bottom electrode.

Sidewall angle α varies from about 70° to 90° depending on the ratio of noble gas to oxidant in MTJ etch 33. For example, the sidewall angle becomes greater as the Ar/CH₃OH flow rate ratio becomes closer to 1:1. Moreover, the HM and DARC etch rates slow with increasing oxidant content in the MTJ etch which means higher selectively with respect to underlying MTJ layers. In other words, a DARC thickness t4, where t4<t3′, may remain after the MTJ etch when using noble gas/oxidant flow rate ratios proximate to 1:1. In other embodiments when IBE or RIE is employed with pure noble gas, or with a noble gas/oxidant ratio of around 10:1 or higher, all of the DARC may be consumed and a top portion of the HM 15 may also be etched away during the MTJ etch. Generally, the higher risk of MTJ sidewall damage with higher oxidant content in the MTJ etch must be balanced with the benefit of higher etch selectivity when determining the optimum noble gas/oxidant flow rate ratio.

Another important consideration is that IBE or RIE with pure noble gas has a more pronounced shadow effect in which small gaps between adjacent MTJ sidewalls are more difficult to clean out (remove all residue), especially in locations proximate to bottom electrode top surface 10t. Therefore, at least a limited amount of oxidant is desirable in the MTJ etch 33 to prevent unwanted erosion of the bottom electrode 10. According to one preferred embodiment, the noble gas/oxidant flow rate ratio should be between 98:2 and 1:1.

In some embodiments, all etch steps 30, 31p, 33 may be performed in the same etch chamber within a sputter deposition mainframe to enhance throughput. When a RIE process chamber is employed for one or more of the aforementioned etch steps, there is an upper electrode, a lower electrode (electrostatic chuck) on which one or more wafers are held in place, and a gap between each wafer and upper electrode (not shown). Preferably, a first RF power between 600 and 3000 Watts is applied to the upper electrode, and a second RF power from 400 to 3000 Watts is applied to the lower electrode in order to generate and sustain plasma in the gap between the two electrodes. In addition, the RIE chamber pressure must be sufficiently high enough to sustain a stable plasma, but is not more than 3 mTorr.

MTJ etch 33 typically comprises a main etch portion during a first period of time that ends when an end point is reached. As described in related patent application Ser. No. 15/668,113, an optical emission spectroscopy (OES) system may be employed to monitor the progress of RIE etching in real time. In one preferred embodiment, the flow rate ratio of noble gas/oxidant is increased during the over etch portion to minimize chemical damage to MTJ sidewalls. In addition, RF power during the over etch portion may be decreased to 75 Watts or less at both of the upper and lower electrodes to minimize the amount of bottom electrode material that is etched, and redeposited on MTJ sidewall 20.

As depicted in FIG. 8, the present disclosure encompasses an optional IBE or plasma etch 34 wherein the MTJ etch conditions related to noble gas/oxidant flow rate ratio are substantially maintained. Ions during an IBE are directed at an angle β that is between 0° and 90° with respect to substrate 10. In a preferred embodiment, a low angle from 0° to 45° is used during an initial period, a high angle from 70° to 90° is applied during a middle period, and a low angle is applied again during a final period of etch step 34. When IBE is employed, etch step 34 is referred to as high pan angle trimming and is typically performed in a different mainframe than used for MTJ etch 33.

In an alternative embodiment, etch step 34 comprises a plasma etch wherein a plasma is generated with a RF or DC power ≤100 Watts and pure noble gas or with a combination of noble gas and one or more oxidants described previously. The plasma is directed orthogonal to the substrate (β=90°) in an etch chamber that may be in the same mainframe as employed for the subsequent encapsulation process. In all embodiments, etch step 34 is incorporated in the MTJ etch process flow as a cleaning measure to ensure that MTJ sidewalls and substrate top surface 10t are substantially free of residue. The wafer on which the plurality of MTJ cells is fabricated is typically rotated during an IBE step but is not rotated during a RIE or plasma etch.

Referring to FIG. 9, an encapsulation layer 25 that is comprised of a dielectric material is deposited over the MTJ array after essentially clean sidewalls 20 are formed. The encapsulation layer may comprise one or more sub-layers and fills the gaps between adjacent MTJ cells. In one embodiment, a first sub-layer 25a with a thickness h1 from 5 to 250 Angstroms is conformally deposited on the plurality of MTJ cells and on substrate top surface 10t. Then a second sub-layer 25b having a thickness h2 up to 2000 Angstroms is deposited on the first sub-layer. Each of sub-layers 25a, 25b is one or more of SiN, SiO₂, SiON, SiC, TaOx, MgO, Al₂O₃, AlN, BN, or the like that is deposited by physical vapor deposition (PVD), chemical vapor deposition (CVD), ion beam deposition (IBD), or atomic layer deposition (ALD). The encapsulation process is preferably performed without breaking the vacuum in the process chamber used for the IBE or plasma etching.

Thereafter, a chemical mechanical polish (CMP) process is performed to form a top surface 25t on the encapsulation layer that is coplanar with HM top surface 15t. Thus, the CMP process removes any material above a plane that includes the HM top surface.

Referring to FIG. 10, the plurality MTJ cells formed by an etch process of the present disclosure is depicted from a top-down view after the CMP or an alternative planarization step. MTJ cell 1a is shown in the same row as MTJ cell 1b above bottom electrode 10, and MTJ cells 1c, 1d (above bottom electrode 10-1) are in the same columns as MTJ cells 1a and 1b, respectively. As explained previously, the MTJ cells are depicted with a circular shape but may have elliptical or polygonal shapes in other embodiments. Generally, millions of MTJ cells are formed in an array but only four are illustrated here to simplify the drawing.

Thereafter, a top electrode layer comprised of a plurality of parallel conductive lines (not shown) is formed by a conventional method on the MTJ cells and encapsulation layer 25 as appreciated by those skilled in the art. A first top electrode line may contact a top surface of MTJ cells 1a, 1c while a second top electrode line contacts top surface in MTJ cells 1b, 1d. Conductive lines in the top electrode layer are preferably formed along the y-axis direction that is orthogonal to the conductive lines along the x-axis direction in the bottom electrode layer.

According to a second embodiment of the etch process flow of the present disclosure, HM thickness t2 in the POR scheme may be increased to t5 in HM 15x as illustrated in FIG. 11 where t5 is substantially larger than t1. For example, t5 may be proximate to 630 Angstroms instead of t1=480 Angstroms in the POR scheme. In the exemplary embodiment, DARC 16 has POR thickness t2, and thickness d0 of about 2600 Angstroms in the photoresist layer 17 is maintained from the first embodiment. A value for d0 larger than 2600 Angstroms is not desired since the process window for forming photoresist islands where the aspect ratio d0/w1 is substantially higher than 4 is significantly reduced compared with the preferred embodiments, which translates to lower device yields. As described previously, the first etch step 30 transfers the photoresist pattern through the DARC to give a thinner photoresist thickness d, and stops on HM top surface 15t.

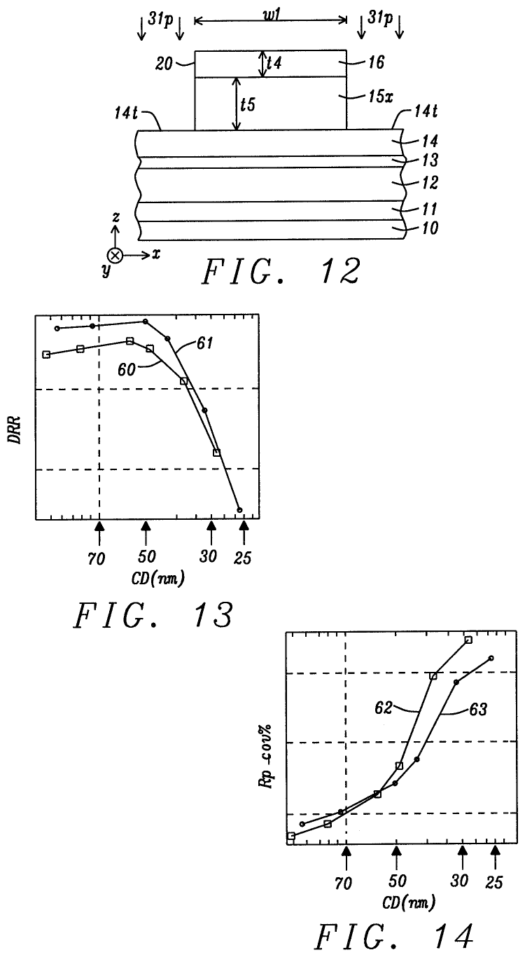

Referring to FIG. 12, the second etch 31p retains the conditions described earlier in the first embodiment shown in FIG. 6 and stops on FL top surface 14t. In this case, the thicker HM 15x ensures that the photoresist layer 17 is entirely removed during the second etch. Although the exemplary embodiment shows a thickness t4, where t4<t2, for the DARC, the DARC may be completely etched away in other embodiments depending on the DARC/HM etch rate ratio, and the thickness ratio t5/t2. In embodiments where the DARC has oxygen content as in SiON, complete DARC removal before MTJ etch is anticipated to advantageously minimize MTJ sidewall damage by reducing the oxygen content in the Ar:oxidant ratio in subsequent MTJ etch 33.

Thereafter, the etch process of the present disclosure comprises MTJ etch 33 and an optional IBE or plasma cleaning step 34 before encapsulation and planarization steps provide a plurality of MTJ cells including MTJ cell 1a that is surrounded by encapsulation layer 25 as shown in FIG. 9.

The present disclosure also anticipates an alternative embodiment where a combination of a thicker DARC 16X and thicker HM 15X may be employed to ensure photoresist 17 is completely removed at the end of the HM etch 31p. For example, in the experiment described below, DARC thickness t3 may be substantially larger than the HM thickness t5 while both t3 and t5 are considerably higher than conventional thickness values of t2 and t1, respectively, for DARC and HM layers.

We have demonstrated the benefits of the combined physical/chemical etch process of the present disclosure with results from an experiment where a series of MTJ cells with various diameters (w1 in FIGS. 4-8) were fabricated. Each MTJ stack of layers in all experiments included a MgO tunnel barrier layer between a CoFeB free layer and a CoFeB reference layer, a Ta hard mask, and a seed layer with an uppermost NiCr layer. A POR etch scheme comprising etch steps 30-32 (FIGS. 1-3) before the MTJ etch was applied to one wafer and used as a reference. For the second wafer, etch steps 30, and 31p (FIGS. 5-6) were performed before the MTJ etch 33, and the O₂ etch 32 was omitted since the photoresist layer was completely removed in etch step 31p. In the POR example, a commercially available photoresist was used to provide a thickness d0=2600 Angstroms before etch, DARC (SiON) thickness t2=300 Angstroms, and HM (Ta) thickness t1=480 Angstroms. For the second wafer, d0 was maintained from the POR scheme, DARC (SiON) thickness was increased to t3=900 Angstroms, and HM thickness was increased to t5=630 Angstroms.

In both cases, the Ta/DARC etch steps were performed with a RIE comprised of 50 sccm CF₄. The Ta/DARC etching was performed in two steps with an intermediate passivation step comprised of H₂O or O₂ treatment, or exposing the wafer to air. The MTJ etch for both examples was a RIE comprising 97.5:2.5 Ar/CH₃OH flow rate ratio, a RF power of 1500 Watts (upper electrode), 1100 Watts (lower electrode), a 15 sccm flow rate for the combined gas mixture, and a 3 mTorr pressure. An annealing step at 400° C. was performed for about 2 hours after an encapsulation process was used to isolate adjacent MTJ cells.

Results are shown in FIG. 13 where MR ratio is plotted as a function of CD where CD ranges from about 70 nm to 25 nm. We find that MR ratio (DRR) is increased for the wafer (curve 61) processed according to an embodiment of the present disclosure in comparison with the POR example (curve 60).

Referring to FIG. 14, Rp_cov % is plotted as a function of CD. Here, Rp_cov % is substantially the same in both examples from about 50 nm to 70 nm. However, Rp_cov % is significantly improved (lower) for MTJ cells smaller than 50 nm that were processed according to an embodiment of the present disclosure (curve 63) compared with the POR example (curve 62).

Our results confirm that when a HM etch includes an oxidant to passivate HM sidewalls and there is sufficient DARC thickness and HM thickness to guarantee no photoresist layer remains after the HM etch, then MR ratio and Rp_cov % are improved while maintaining other MTJ performance values including thermal stability and the RA product. Ideally, all etch steps and the encapsulation process should be done in one platform having multi-chambers, including a dedicated chamber for each of the HM and MTJ RIE steps, IBE for HM, MTJ, or sidewall cleaning, a plasma etch chamber for MTJ sidewall cleaning, and PVD/CVD chamber for encapsulation. Practically, there may be three separate platforms with one each assigned to RIE for HM and RIE for MTJ, IBE and PVD, and plasma etching and PVD.

While this disclosure has been particularly shown and described with reference to, the preferred embodiment thereof, it will be understood by those skilled in the art that various changes in form and details may be made without departing from the spirit and scope of this disclosure.

1. A method of etching a magnetic tunnel junction (MTJ) stack of layers, comprising:
providing a MTJ stack of layers on a first electrode wherein the MTJ stack of layers includes a hard mask (HM) on a first stack of layers, and forming a second stack of layers comprising a dielectric antireflective coating (DARC) with a first thickness on the HM, and a photoresist layer on the DARC;
forming a pattern with a critical dimension (CD) in the photoresist layer and transferring the pattern through the DARC with a first etch process that is an ion beam etch (IBE) or a reactive ion etch (RIE) wherein the pattern after the first etch process includes at least a sidewall that extends from a top surface of the DARC to a top surface of the HM;
performing a second etch that is an IBE or RIE wherein the pattern in the DARC is transferred through the HM, and wherein the first thickness is sufficiently large such that the photoresist layer is entirely removed before the end of the second etch, and the sidewall extends from a DARC top surface to a top surface of the first stack of layers, and wherein the second etch comprises one or more oxidants that passivate the sidewall; and
performing a third (MTJ) etch that is one or both of a RIE or IBE comprised of a noble gas and the one or more oxidants wherein the MTJ etch transfers the pattern through the first stack of layers, and stops at a top surface of the first electrode and thereby forms a plurality of MTJ cells.

2. The method of claim 1 wherein the first and second etches and the MTJ etch are all RIE or all IBE, and are performed in a first process chamber.

3. The method of claim 2 further comprised of a cleaning step that is an IBE or plasma etch performed after the MTJ etch, and wherein a plasma is generated from a gas mixture comprised of a noble gas and the one or more oxidants.

4. The method of claim 1 wherein the one or more oxidants is selected from air, 0₂, methanol, ethanol, H₂0₂, H₂0, N₂0, NH₃, and CO.

5. The method of claim 1 wherein the first etch is an IBE and comprises a noble gas that is Ar, Kr, Xe, or Ne.

6. The method of claim 1 wherein the second etch is an IBE and comprises a noble gas that is Ar, Kr, Xe, or Ne.

7. The method of claim 1 wherein the first etch is a RIE and comprises a fluorocarbon or chlorocarbon.

8. The method of claim 1 wherein the second etch is a RIE and comprises a fluorocarbon or chlorocarbon.

9. The method of claim 1 wherein the first etch further comprises oxygen in order to passivate the sidewall.

10. The method of claim 1 wherein the MTJ stack of layers is formed in a magnetoresistive random access memory (MRAM), spin torque transfer (STT)-MRAM, spin torque oscillator (STO), sensor, or biosensor.

11. The method of claim 1 wherein the first stack of layers comprises a free layer (FL), a reference layer (RL), and a tunnel barrier between the FL and RL.

12. The method of claim 1 wherein the first thickness is substantially larger than a thickness of the hard mask.

13. A method of etching a magnetic tunnel junction (MTJ) stack of layers, comprising:
providing a MTJ stack of layers on a first electrode wherein the MTJ stack of layers includes a hard mask (HM) on a first stack of layers, and forming a second stack of layers comprising a dielectric antireflective coating (DARC) on the HM, and a photoresist layer on the DARC wherein the HM is a metal, alloy, or metal nitride having a first thickness;
forming a pattern with a critical dimension (CD) in the photoresist layer and transferring the pattern through the DARC with a first etch process that is an ion beam etch (IBE) or a reactive ion etch (RIE) wherein the pattern after the first etch process has a sidewall that extends from a top surface of the photoresist layer to a top surface of the HM;
performing a second etch that is an IBE or RIE wherein the pattern in the DARC is transferred through the HM, and wherein the first thickness is sufficiently large such that the photoresist layer is entirely removed and the sidewall extends to a top surface of the first stack of layers, and wherein the second etch comprises one or more oxidants that passivate the sidewall; and
performing a third (MTJ) etch that is one or both of a RIE or IBE comprised of a noble gas and the one or more oxidants wherein the MTJ etch transfers the pattern through the first stack of layers, and extends the sidewall to a top surface of the first electrode and thereby forms a plurality of MTJ cells.

14. The method of claim 13 wherein the first and second etches and the MTJ etch are all RIE or all IBE, and are performed in a first process chamber.

15. The method of claim 14 further comprised of a cleaning step that is an IBE or plasma etch performed after the MTJ etch, and wherein a plasma is generated from a gas mixture comprised of a noble gas and the one or more oxidants.

16. The method of claim 13 wherein the one or more oxidants is selected from air, 0₂, methanol, ethanol, H₂0₂, H₂0, N₂0, NH₃, and CO.

17. The method of claim 13 wherein the first etch is an IBE and comprises a noble gas that is Ar, Kr, Xe, or Ne.

18. The method of claim 13 wherein the second etch is an IBE and comprises a noble gas that is Ar, Kr, Xe, or Ne.

19. The method of claim 13 wherein the first etch is a RIE and comprises a fluorocarbon or chlorocarbon.

20. The method of claim 13 wherein the second etch is a RIE and comprises a fluorocarbon or chlorocarbon.

21. The method of claim 13 wherein the first etch further comprises oxygen in order to passivate the sidewall.

22. The method of claim 13 wherein the MTJ stack of layers is formed in a magnetoresistive random access memory (MRAM), spin torque transfer (STT)-MRAM, spin torque oscillator (STO), sensor, or biosensor.

23. The method of claim 13 wherein the DARC has a thickness substantially greater than the first thickness.
